(19) United States
(12) Patent Application Publication
(10) Pub. No.: US 2011/0076623 A1
(43) Pub. Date: Mar. 31, 2011

(54) METHOD FOR REWORKING SILICON-CONTAINING ARC LAYERS ON A SUBSTRATE

(75) Inventor: Fitrianto, Albany, NY (US)

(73) Assignee: TOKYO ELECTRON LIMITED, Tokyo (JP)

(21) Appl. No.: 12/568,885

(22) Filed: Sep. 29, 2009

(51) Int. Cl. G03F 7/20

(52) U.S. Cl. 430/323

(57) ABSTRACT

A method is provided for reworking film structures containing silicon-containing anti-reflective coating (SiARC) layers in semiconductor device manufacturing. The method includes providing a substrate containing a film stack that includes SiARC layer thereon, and a resist pattern formed on the SiARC layer. The method further includes removing the resist pattern from the SiARC layer, exposing the SiARC layer to process gas containing ozone (O₃) gas to modify the SiARC layer, treating the modified SiARC layer with a dilute hydrofluoric acid (DHF) liquid, and centrifugally removing the modified SiARC layer from the substrate.

### FIELD OF THE INVENTION

The invention is related to substrate processing, in particular, to methods for reworking film structures containing a silicon-containing anti-reflective coating (SiARC) layer on a substrate.

### BACKGROUND OF THE INVENTION

Lithographic processes using radiation sensitive material (also referred to herein as “resist”) are widely used in the manufacture of semiconductor devices and other patterned structures. In track photolithographic processing used in the fabrication of semiconductor devices, the following types of processes may be performed in sequence: photoresist coating that coats a photoresist solution on a semiconductor wafer to form a photoresist film, heat processing to cure the coated photoresist film, exposure processing to expose a predetermined pattern on the photoresist film, heat processing to promote a chemical reaction within the photoresist film after exposure, developing processing to develop the exposed photoresist film and form a photoresist pattern, etching a fine pattern in an underlying layer or substrate using the photoresist pattern, etc.

In a photolithography process, various parameters may affect a profile of the photoresist pattern. The profile of the photoresist pattern may have some defects caused by the various process parameters of a spin coating process, the heat processing, the exposure processing and the developing processing. When a photoresist pattern having defects is employed in an etching process for forming a fine pattern in a semiconductor device, the fine pattern may also have defects in accordance with defects in the photoresist pattern. Thus, when the photoresist pattern has the defects, a rework process may be performed on the defective photoresist pattern. In the rework process, a new photoresist pattern is formed on the semiconductor substrate after removing the defective photoresist pattern from the semiconductor substrate. The rework process can include a dry cleaning process such as an ashing process using oxygen (O₂) plasma, or a wet cleaning process using an organic stripper solution. When the photoresist pattern is removed using an oxygen plasma in an ashing process, an exposed surface of the semiconductor substrate may be damaged and electrical characteristics of a semiconductor device provided on the substrate may deteriorate.

In the photolithographic processing, an organic or inorganic anti-reflection coating (ARC) layer may be deposited on a layer to be etched before forming the photoresist pattern. The ARC layer may be used to reduce reflection of light from the layer to etched while forming the photoresist pattern on the ARC layer by an exposure process. For example, the ARC layer may prevent a standing wave effect caused by interference between incident light toward a photoresist film and reflected light from the layer to be etched.

Advanced organic and inorganic ARC layers have been developed for increased density of features that improve the cost per function ratio of the microelectronic device being manufactured. As the drive toward smaller and smaller features continues, several new problems in the manufacture of these very small features are becoming visible. Silicon-containing ARC (SiARC) layers are promising candidates for hard masks because Si-content of SiARC layers may be tuned to provide high etch selectivity to photoresist. However, removal of many new materials used in advanced ARC layers, for example SiARC layers, during a rework process, is problematic and new processing methods for removing these materials and other layers are needed for microelectronic device production.

### SUMMARY OF THE INVENTION

Exemplary embodiments of the invention provide methods of reworking a silicon-containing ARC (SiARC) layer on a substrate, for example due to a defective overlying photoresist pattern. According to some embodiments, the SiARC layer may overlie an optical mask layer, for example an organic planarization layer (OPL) coating on the substrate.

According to one embodiment, a method is provided for reworking a substrate. The method includes providing a substrate containing a SiARC layer thereon, and a resist pattern formed on the SiARC layer, removing the resist pattern from the SiARC layer, exposing the SiARC layer to a process gas containing ozone (O₃) gas to form a modified SiARC layer, treating the modified SiARC layer with a dilute hydrofluoric acid (DHF) liquid, and centrifugally removing the modified SiARC layer from the substrate.

According to another embodiment, the method includes providing a substrate containing an OPL coating thereon, a SiARC layer on the OPL coating, and a resist pattern formed on the SiARC layer. The method further includes removing the resist pattern from the SiARC layer, modifying the SiARC layer and the OPL coating by exposing the SiARC layer to a mixture of O₃ gas and water (H₂O) vapor, treating the modified SiARC layer and the modified OPL coating with a DHF liquid, and centrifugally removing modified SiARC layer and the modified OPL coating from the semiconductor substrate.

### BRIEF DESCRIPTION OF THE DRAWINGS

The accompanying drawings, which are incorporated in and constitute a part of this specification, illustrate embodiments of the invention and, together with a general description of the invention given above, and the detailed description given below, serve to explain the principles of the invention.

FIGS. 1A-1F are schematic cross-sectional views for a method of reworking a film structure containing a SiARC layer according to an embodiment of the invention;

FIG. 2 is a schematic diagram of a processing system for modifying SiARC layers according to an embodiment of the invention;

FIG. 3 is a schematic diagram of a wet processing system for treating and centrifugally removing layers from a substrate according to an embodiment of the invention;

FIG. 4 shows processing results for removal of SiARC layers using different processing recipes;

FIGS. 5A-5F are schematic cross-sectional views for a method of reworking a film structure containing a SiARC layer and an OPL coating according to another embodiment of the invention;

FIG. 6 is a simplified process flow diagram for a method of reworking a film structure containing a SiARC layer according to an embodiment of the invention; and

FIG. 7 is a simplified process flow diagram for a method of reworking a film structure containing a SiARC layer and an OPL coating according to another embodiment of the invention.

### DETAILED DESCRIPTION OF SEVERAL EMBODIMENTS

Embodiments of the invention provide methods for reworking film structures containing SiARC layers and other layers utilized for semiconductor device manufacturing. The methods include a first processing step for modifying a SiARC layer and a second wet processing step for removing the modified SiARC layer and optionally one or more underlying layers. The SiARC layers may include Si-containing polymers that are cross-linked that have different Si-contents. Exemplary SiARC layers that are currently used for photolithography may have a silicon-content of 17% Si (SiARC 17%) or a silicon-content of 43% Si (SiARC 43%). For example, SiARC layers are commercially available as Sepr-Shb Aseries SiARC layers from Shin Etsu Chemical Co., Ltd. According to embodiments of the invention, the SiARC layer may have a Si-content between about 10% and about 40%, or a Si-content greater than about 40%.

One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Furthermore, it is understood that the various embodiments shown in the figures are illustrative representations and are not necessarily drawn to scale.

Reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention.

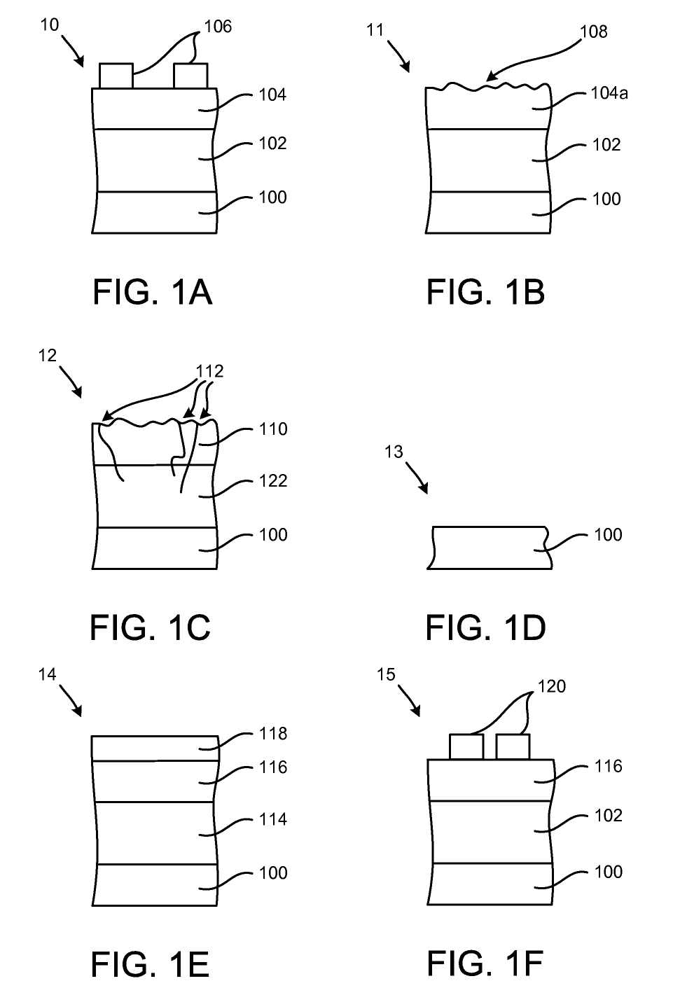

FIGS. 1A-1F are schematic cross-sectional views for a method of reworking a film structure containing a SiARC layer according to an embodiment of the invention. In FIG. 1A, film structure 10 contains a substrate 100, an optical mask layer 102 on the substrate 100, and a SiARC layer 104 on the optical mask layer 102. According to one embodiment, the optical mask layer 102 may contain or consist of an organic planarization layer (OPL coating). According to some embodiments of the invention, the optical mask layer 102 may be omitted and the SiARC layer 104 deposited directly on the substrate 100 or on a dielectric layer, a semiconductor layer, or a conductor layer. The SiARC layer 104 may, for example, be applied using spin coating technology, or a vapor deposition process.

The film structure 10 further contains a resist pattern 106 that is used as a mask for defining a pattern to be etched into the SiARC layer 104, the optical mask layer 102, and the substrate 100. According to other embodiments of the invention, the film structure 10 may contain additional layers, for example an oxide layer (not shown) between the optical mask layer 102 and the substrate 100. In one example the substrate 100 may contain a low-dielectric constant (low-k) layer to be etched and patterned.

The resist pattern 106 may contain a 248 nm (nanometer) photoresist, a 193 nm photoresist, a 157 nm photoresist, an EUV (extreme ultraviolet) photoresist, or an electron beam sensitive resist. A resist layer may be deposited using a track system. For example, the track system can comprise a Clean Track ACT 8, ACT 12, or Lithius resist coating and developing system commercially available from Tokyo Electron Limited (TEL). Other systems and methods for forming a photo-resist layer on a substrate are well known to those skilled in the art of spin-on resist technology.

Following deposition of a photoresist layer and one or more curing processes, a photolithography process may be performed for transferring a pattern from a reticle or mask to the photoresist layer. After the photoresist layer is selectively exposed to electromagnetic (EM) radiation using the reticle or mask, the exposed photoresist layer is developed by a developer solution to form the photoresist pattern 106 depicted in FIG. 1A. The photoresist pattern 106 covers areas of the underlying SiARC layer 104.

The exposure to EM radiation through a reticle is performed in a dry or wet photo-lithography system. The image pattern can be formed using any suitable conventional stepping lithographic system, or scanning lithographic system. For example, the photo-lithographic system may be commercially available from ASML Netherlands B.V. (De Run 6501, 5504 DR Veldhoven, The Netherlands), or Canon USA, Inc., Semiconductor Equipment Division (3300 North First Street, San Jose, Calif. 95134. In some examples, the EM radiation can include KrF radiation (248 nm wavelength) or higher wavelength radiation. The developing process can include exposing the substrate to a developing solvent in a developing system, such as a track system. For example, the track system can comprise a Clean Track ACT 8, ACT 12, or Lithius resist coating and developing system commercially available from Tokyo Electron Limited (TEL).

The optical mask layer 102 may contain an OPL coating that can include a photo-sensitive organic polymer or an etch type organic compound. For instance, the photo-sensitive organic polymer may be polyacrylate resin, epoxy resin, phenol resin, polyamide resin, polyimide resin, unsaturated polyester resin, polyphenylenether resin, polyphenylenesulfide resin, or benzocyclobutene (BCB). These materials may be formed using spin-on techniques. The OPL coating may be an organic material (e.g., (CHₓ)ₙ) that forms a cross-linked structure during a curing process.

Following formation of the photoresist pattern 106, an after-development-inspection system (ADI) may be used to examine the photoresist pattern 106 at a plurality of test areas to determine if it has been correctly manufactured. The ADI can determine a critical dimension (CD) and alignment or the presence of any residue or debris on the film structure 10. CD commonly refers to a size or width of a feature formed in the photoresist pattern 106, or a dimension between features etched in the photoresist pattern 106. Key requirements for the processing of semiconductor wafers are tight CD control, tight profile control, and tight uniformity control—both within-wafer and wafer-to-wafer. For example, variations in CD measurements, profile measurements, and uniformity measurements are often caused by variations in temperature profile across a wafer, variations in thermal response from wafer to wafer, and variations in temperature profiles between substrate heaters.

The ADI may, for example, be a scanning electron microscope (SEM) or a light scattering system such as an optical digital profilometry (ODP) system. The ODP system may include a scatterometer, incorporating beam profile ellipsometry and beam profile reflectometry (reflectometer), commercially available from Therma-Wave, Inc. (1250 Reliance Way, Fremont, Calif. 94539) or Nanometrics, Inc. (1550 Buckeye Drive, Milpitas, Calif. 95035). ODP software is available from Timbre Technologies Inc. (2953 Bunker Hill Lane, Santa Clara, Calif. 95054).

If a feature dimension of the photoresist pattern 106 is not within tolerance specification or if a residue/defect is detected, the photoresist pattern 106 must be reworked before etching features in the substrate 100. According to some embodiments of the invention, the rework includes not only removing the photoresist pattern 106 from the film structure 10 but also the SiARC layer 104 and the optical mask layer 102.

The photoresist pattern 106 in FIG. 1A may be removed from the SiARC layer 104 using methods well known to those in the art. In a first example, the photoresist pattern 106 may be removed from the SiARC layer 104 using a conventional dry ashing process, or using a sulfuric acid hydrogen peroxide mixture (SPM) in a wet process or a developer solution/photoresist solvent like propylene glycol monomethyl ether acetate (PGMEA) in a Clean Track system. In a second example, the photoresist pattern 106 may be removed from the SiARC layer 104 by exposure to a process gas containing ozone (O₃), followed by a wet spin-off process that centrifugally removes remains of the photoresist pattern 106 in the presence of de-ionized water (DIW) or an alkaline solution. In the second example, removal of the photoresist pattern 106 may be carried out without plasma damage and without formation of residues on the SiARC layer 104.

Removal of the photoresist pattern 106 from the SiARC layer 104 may damage the exposed SiARC layer 104a. FIG. 1B schematically shows a film structure 11 containing a surface roughened region 108 on the SiARC layer 104. The presence of the surface roughened region 108 can require reworking of the SiARC layer 104 and the optical mask layer 102. The inventors have realized that conventional dry and wet processing methods are unable to satisfactorily remove the SiARC layer 104, or the SiARC layer 104 and the optical mask layer 102. For example, dry ashing methods frequently create non-volatile hard residues that remain on the substrate 100. Accordingly, embodiments of the invention provide methods for removing the SiARC layer 104, or the SiARC layer 104 and the optical mask layer 102 from the substrate 100. The inventive methods may be used to replace conventional ashing methods and combine dry and wet processing on a single wafer platform. The dry processing can modify the photoresist by oxidation to form a water soluble species, without forming a hard residue that remains on the substrate 100.

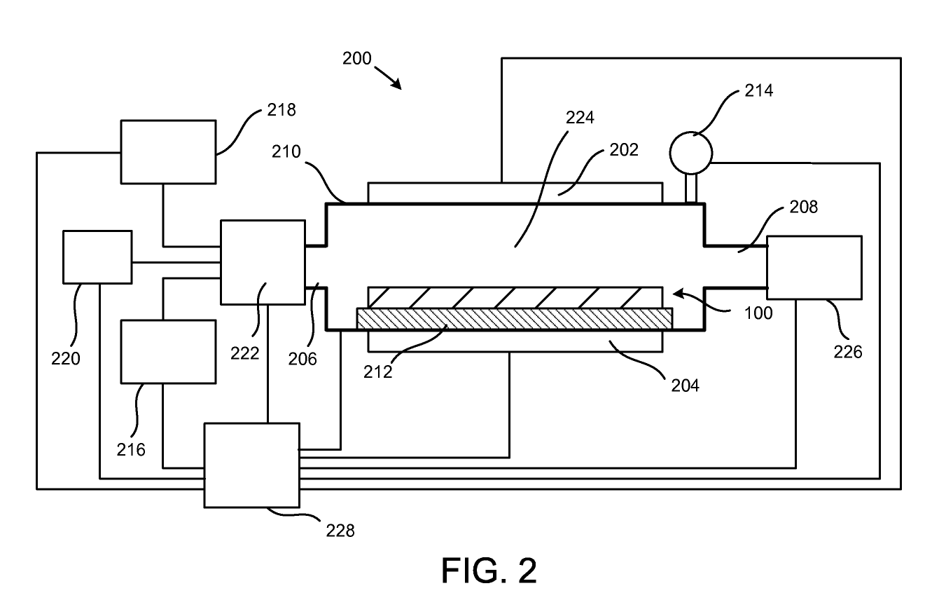

According to one embodiment of the invention, following removal of the photoresist pattern 106, the method includes a first process for modifying the SiARC layer 104. The first process may be performed in a first processing system 200 schematically shown in FIG. 2. The first processing system 200 contains a process chamber 210 that includes an upper heater 202, a lower heater 204, a substrate holder 212 for supporting the substrate 100, a process gas inlet 206, a process gas outlet 208, a pressure gauge 214 for measuring a gas pressure in the process chamber 210, and an exhaust system 226 for exhausting the gaseous environment in the process chamber 210 and providing a reduced pressure in the processing region 224. The first processing system 200 further includes an O₃ generator 218, a H₂O vaporizer 216, a N₂ gas supply system 220, and a gas heater 222. The gas heater 222 may be configured for heating a process gas to a temperature between about 80° C. and about 150° C., or between about 100° C. and about 120° C.

The first processing system 200 further includes a controller 228 that can be coupled to and control the process chamber 210, the upper heater 202, the lower heater 204, the substrate holder 212, the pressure gauge 214, the exhaust system 226, the O₃ generator 218, the H₂O vaporizer 216, the N₂ gas supply system 220, and the gas heater 222. Alternatively, or in addition, controller 228 can be coupled to one or more additional controllers/computers (not shown), and controller 228 can obtain setup and/or configuration information from an additional controller/computer. The controller 228 can comprise a number of applications for controlling one or more of the processing elements described above. For example, controller 228 can include a graphic user interface (GUI) component (not shown) that can provide easy to use interfaces that enable a user to monitor and/or control one or more processing elements.

The first processing system 200 may be configured to process 200 mm substrates, 300 mm substrates, or larger-sized substrates. In fact, it is contemplated that the deposition system may be configured to process substrates, wafers, or LCDs regardless of their size, as would be appreciated by those skilled in the art. Therefore, while aspects of the invention will be described in connection with the processing of a semiconductor substrate, the invention is not limited solely thereto. Alternately, a batch first processing system capable of processing multiple substrates simultaneously may be utilized for the first process for modifying the SiARC layer 104 as described in the embodiments of the invention.

The first process can include disposing the substrate 100 on the substrate holder 212 in the process chamber 210 and heating the process chamber 210 to a desired temperature using the upper heater 202 and the lower heater 204. For example, the process chamber 210 may be heated to approximately 105° C. by heaters 202 and 204. Thereafter, a process gas is flowed from the gas heater 222 into the processing region 224 above the substrate 100 for modifying the SiARC layer 104.

According to one embodiment, the process gas includes O₃ gas that is flowed from the O₃ generator 218 into the gas heater 222 where it is heated and thereafter the process gas is flowed into the process chamber 210 and exposed to substrate 100 in the processing region 224. Exemplary processing conditions include a gas flow rate of 4 liters/minute with an O₃ gas concentration of 9% by volume (200 g/m³), balance O₂. A temperature of the gas heater 222 can be approximately 150° C. and a gas pressure in the processing region 224 can be approximately 75 kPa. According to another embodiment, N₂ gas may be provided from the N₂ supply system 220 and mixed with the O₃ gas in the gas heater 222.

According to another embodiment, the process gas includes a mixture of O₃ gas and H₂O vapor. The H₂O vapor can be generated in the H₂O vaporizer at a temperature of approximately 128° C., and mixed with O₃ gas in the gas heater 222. The process gas containing the heated mixture of O₃ gas and H₂O vapor is flowed into the process chamber 210 and exposed to the substrate 100 in the processing region 224. According to another embodiment, N₂ gas may be provided from the N₂ supply system 220 and mixed with the mixture of O₃ gas and H₂O vapor in the gas heater 222.

FIG. 1C shows a film structure 12 containing a modified SiARC layer 110 and a modified optical mask layer 122 following a first process using O₃ gas in the absence of H₂O vapor according to one embodiment of the invention. According to another embodiment, the first process may contain a mixture of O₃ gas and H₂O vapor. According to some embodiments of the invention, the formation of the modified SiARC layer 110 and the modified optical mask layer 122 enables subsequent complete removal of the modified SiARC layer 110 and the modified optical mask layer 122 in a second wet process that includes exposing the modified SiARC layer 110 and the modified optical mask layer 122 to DHF liquid and centrifugally removing the layers. It is speculated that subsequent complete removal of the modified SiARC layer 110 and modified optical mask layer 122 in the second wet process is facilitated by damage in the form of cracks 112 in the modified SiARC layer 110 and the modified optical mask layer 122. It is further speculated that the SiARC layer 104 is modified by the O₃ gas exposure, or by the O₃ gas and H₂O vapor exposure, to become more “SiO₂-like” and therefore more easily removed in the second wet process. However, although not shown in FIGS. 1A-1D, according to some embodiments of the invention, the exposure of the SiARC layer 104 to the O₃ gas, or to the O₃ gas and H₂O vapor, may not damage the optical mask layer 102 prior to removal of the modified SiARC layer 110 and the optical mask layer 102 in the DHF removal step. Exemplary concentrations of the DHF liquid include about 1% (volume:volume) HF in H₂O, less than about 1% HF in H₂O, or less than about 0.5% HF in H₂O.

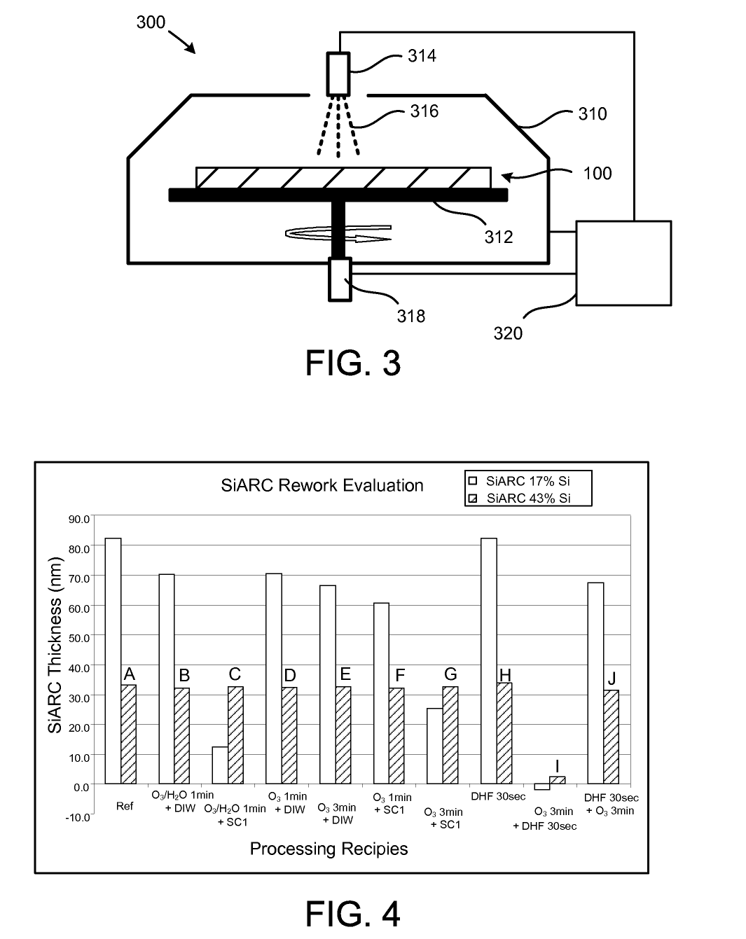

According to embodiments of the invention, the second wet process removes the modified SiARC layer 110 and the modified optical mask layer 122 from the substrate 100. The second wet process may be performed in a second processing system 300 schematically shown in FIG. 3. The second processing system 300 can be a semi-closed wet spin module for treating and centrifugally removing films or layers from a substrate by spinning the substrate. The semi-closed configuration allows fume control and minimizes exhaust volume. The second processing system 300 contains a process chamber 310 that includes a substrate holder 312 for supporting, heating, and rotating (spinning) the substrate containing the film structure 12, a rotating means 318 (e.g., a motor), and a liquid delivery nozzle 314 configured for providing a liquid 316 to an upper surface of the film structure 12. According to other embodiments, the second processing system 300 may include additional liquid delivery nozzles (not shown) for providing different liquids. The liquid delivery nozzle 314 may provide atomic spray of the liquid 316 for good film and particle removal without surface damage. The liquid 316 can include a cleaning liquid, DIW, or a combination thereof. The cleaning liquid can, for example, include DHF, SC1 (NH₄OH/H₂O₂/H₂O), or SC2 (HCl/H₂O₂/H₂O). In some examples, the liquid delivery nozzle 314 may first provide a cleaning liquid to the upper surface of the film structure 12, and thereafter, provide DIW to remove the cleaning liquid. Exemplary rotating speeds can be between about 500 rpm and about 1500 rpm, for example 1000 rpm, during exposure of the upper surface of the film structure 12 to the liquid 316.

The second processing system 300 further includes a controller 320 that can be coupled to and control the process chamber 310, the liquid delivery nozzle 314, and the rotating means 318. Alternatively, or in addition, controller 320 can be coupled to one or more additional controllers/computers (not shown), and controller 320 can obtain setup and/or configuration information from an additional controller/computer. The controller 320 can comprise a number of applications for controlling one or more of the processing elements described above. For example, controller 320 can include a graphic user interface (GUI) component (not shown) that can provide easy to use interfaces that enable a user to monitor and/or control one or more processing elements.

The second processing system 300 may be configured to process 200 mm substrates, 300 mm substrates, or larger-sized substrates. In fact, it is contemplated that the deposition system may be configured to process substrates, wafers, or LCDs regardless of their size, as would be appreciated by those skilled in the art. Therefore, while aspects of the invention will be described in connection with the processing of a semiconductor substrate, the invention is not limited solely thereto. Alternately, a batch first processing system capable of processing multiple substrates simultaneously may be utilized for the second wet process for removing the modified SiARC layer 110 and the modified optical mask layer 122 from the substrate 100 as described in the embodiments of the invention. FIG. 1D shows a film structure 13 containing the substrate 100 following a second wet process for removing the modified SiARC layer 110 and the modified optical mask layer 122.

According to one embodiment, the film structure 12 may be exposed to the DHF liquid and, subsequently, without further exposure to the DHF liquid, the substrate may be rotated to centrifugally remove the modified SiARC layer 110 and the modified optical mask layer 122 from the film structure 12. A DIW exposure and spinning may be used to remove the DHF liquid.

According another embodiment, the film structure 12 may be simultaneously exposed to the DHF liquid and the substrate rotated to centrifugally remove the modified SiARC layer 110 and the modified optical mask layer 122 from the film structure 12. A DIW exposure and spinning may be used to remove the DHF liquid.

According to another embodiment, the film structure 10 containing the photoresist pattern 106 and the SiARC layer 104 shown in FIG. 1A may be removed using a first process that includes an exposure to O₃ gas in the process chamber 210, followed by a second wet process that includes treating the modified SiARC layer 110 and the modified optical mask layer 122 to DHF liquid, and centrifugally removing the layers 110 and 122. A DIW exposure and spinning may be used to remove the DHF liquid.

According to another embodiment, the film structure 10 contains the photoresist pattern 106 and the SiARC layer 104 shown in FIG. 1A may be removed using a first process that includes an exposure to a mixture of O₃ gas and H₂O vapor in the process chamber 210, followed by a second wet process includes exposing the modified SiARC layer 110 and the modified optical mask layer 122 to DHF liquid, and centrifugally removing the layers 110 and 122. A DIW exposure and spinning may be used to remove the DHF liquid.

As shown in FIG. 1E, following the removal of the modified SiARC layer 110 and the modified optical mask layer 122, a new optical mask layer 114, a new SiARC layer 116, and a new photoresist 118 may be deposited on a substrate 100 and a new photoresist patterning process repeated on the film structure 14. FIG. 1F shows a new film structure 15 that includes a new photoresist pattern 120 formed on the new SiARC layer 116.

FIG. 4 shows processing results for removal of SiARC layers using different processing steps. Two different film stacks were studied. The first film stack included a Si substrate, a 50 nm thick SiO₂ layer on the Si substrate, and a circa 80 nm thick SiARC layer with a 17% Si-content (SiARC 17%). The second film stack included a Si substrate, a 50 nm thick SiO₂ layer on the Si substrate, and a circa 35 nm thick SiARC layer with a 43% Si-content (SiARC 43%). The plots in FIG. 4 shows SiARC film thickness as a function of processing recipes A-J, where the SiARC film thickness was measured following the processing. Process recipes B-G included a first processing step in the first processing system 200 and a second wet processing step in the second processing system 300 with simultaneous cleaning liquid or DIW exposure and substrate rotation. Process recipe A denotes unprocessed SiARC 17% and SiARC 43% reference film structures; process recipe B denotes a first processing step of 1 minutes O₃ gas/H₂O vapor exposure followed by a second wet processing step of deionized water (DIW) exposure and substrate rotation; process recipe B denotes a first processing step of 1 minute O₃ gas/H₂O vapor exposure followed by a second wet processing step of SC1 exposure and substrate rotation; and process recipe C denotes a first processing step of 1 minutes O₃ gas exposure (without H₂O vapor) followed by a second processing step of DIW exposure and rotation. Process recipe D denotes a first processing step of 1 minute O₃ gas exposure (without H₂O) followed by a second wet processing step of SC1 exposure with substrate rotation; process recipe E denotes a first processing step of 1 minute O₃ gas exposure (without H₂O) followed by a second wet processing step of DIW exposure and substrate rotation; and process recipe F denotes a first processing step of 1 minute O₃ gas exposure (without H₂O) followed by a second wet processing step of SC1 exposure and substrate rotation; and process recipe G denotes a first processing step of 3 minute O₃ gas exposure (without H₂O) and a second wet processing step of SC1 exposure and substrate rotation. Process recipe H denotes a single processing step of 30 second DHF exposure and substrate rotation in the second processing system 300. Process recipe I denotes a 3 minute O₃ gas exposure (without H₂O) in the first processing system 200 and a second wet processing step of 30 second DHF liquid exposure and substrate rotation in the second processing system 300. Process recipe J denotes a 30 second DHF exposure and rotation in the second processing system 300, followed by a 3 minute O₃ gas exposure (without H₂O) in the first processing system 200.

The results in FIG. 4 show that only process recipe I (3 minute O₃ gas exposure in the first processing system 200, and a second wet processing step of 30 second DHF liquid exposure and substrate rotation in the second processing system 300) resulted in complete or near complete removal of the SiARC 17% and SiARC 43%. Furthermore, process recipes C and G resulted in partial removal of the SiARC 17%.

Additional film stacks containing SiARC 43% were studied. The film stacks included a Si substrate, a 50 nm thick SiO₂ layer on the Si substrate, a 200 nm thick OPL coating layer on the SiO₂ layer, and a 35 nm thick SiARC 43%. Process recipes containing a first processing step of O₃ gas/H₂O vapor exposure of 30 seconds (or greater) followed by a second wet processing step of DHF exposure of 5 seconds (or greater) resulted in complete removal of the OPL coating and the SiARC 43%.

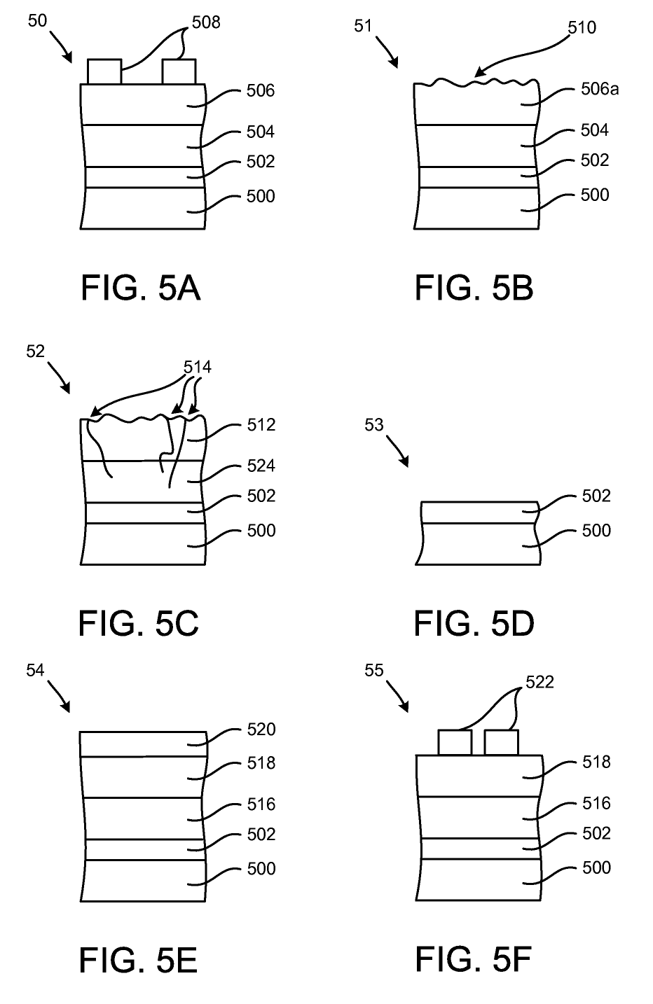

FIGS. 5A-5F are schematic cross-sectional views for a method of reworking a film structure containing a SiARC layer according to another embodiment of the invention. The film structure 50 depicted in FIG. 5A is similar to the film structure 10 depicted in FIG. 1A but contains a substrate containing a low-k layer 500, an oxide layer 502 on the low-k layer 500, an OPL coating 504 on the oxide layer 502, a SiARC layer 506 on the OPL coating 504, and a photoresist pattern 508 on the SiARC layer 506. According to some embodiments of the invention, the oxide layer 502 may be omitted and the OPL coating 504 deposited directly on the low-k layer 500.

The photoresist pattern 508 in FIG. 5A may be removed from the SiARC layer 506 in a rework process using methods well known to those in the art. In a first example, the photoresist pattern 508 may be removed from the SiARC layer 506 using a conventional dry ashing process, or using a sulfuric acid hydrogen peroxide mixture (SPM) in a wet process or a developer solution/photoresist solvent like propylene glycol monomethyl ether acetate (PGMEA) in a Clean Track system. In a second example, the photoresist pattern 508 may be removed from the SiARC layer 506 by exposure to a process gas containing O₃ gas, followed by a wet spin-off process that centrifugally removes remains of the photoresist pattern 508 in the presence of de-ionized water (DIW) or an alkaline solution. In the second example, removal of the photoresist pattern 508 may be carried out without plasma damage and without formation of residues on the SiARC layer 506.

Removal of the photoresist pattern 508 from the SiARC layer 506 may damage the exposed SiARC layer 506a. FIG. 5B schematically shows a film structure 51 containing a surface roughened region 510 on the SiARC layer 506. The presence of the surface roughened region 510 can require reworking of the SiARC layer 506 and the OPL coating 504.

According to one embodiment of the invention, following removal of the photoresist pattern 508, the method includes a first process for modifying the SiARC layer 506 and the OPL coating 504. The first process may be performed in the first processing system 200 schematically shown in FIG. 2 and described above. The first process can include disposing the film structure 51 on the substrate holder 212 in the process chamber 210 and heating the process chamber 210 to a desired temperature using the upper heater 202 and the lower heater 204. For example, the process chamber 210 may be heated to approximately 105° C. Thereafter, a process gas is flowed from the gas heater 222 and into the processing region 224 above the film structure 51 for modifying the SiARC layer 506 and the OPL coating 504.

According to one embodiment, the process gas includes O₃ gas that is flowed from the O₃ generator 218 into the gas heater 222 where it is heated and thereafter the process gas is flowed into the process chamber 210 and exposed to film structure 51 in the processing region 224. Exemplary processing conditions include a gas flow rate of 4 liters/minute with an O₃ gas concentration of 9% by volume (200 g/m³), balance O₂. A temperature of the gas heater 222 can be approximately 150° C. and a gas pressure in the processing region 224 can be approximately 75 kPa. According to another embodiment, N₂ gas may be provided from the N₂ supply system 220 and mixed with the O₃ gas in the gas heater 222.

According to another embodiment, the process gas includes a mixture of O₃ gas and H₂O vapor. The H₂O vapor can be generated in the H₂O vaporizer at a temperature of approximately 128° C. and mixed with O₃ gas in the gas heater 222. The process gas containing the heated mixture of O₃ gas and H₂O vapor is flowed into the process chamber 210 and exposed to the substrate 100 in the processing region 224. According to another embodiment, N₂ gas may be provided from the N₂ supply system 220 and mixed with the mixture of O₃ gas and H₂O vapor in the gas heater 222.

FIG. 5C shows a film structure 52 containing a modified SiARC layer 512 and modified OPL coating 524 following a first process using O₃ gas in the absence of H₂O vapor according to one embodiment of the invention. According to another embodiment, the first process may contain a mixture of O₃ gas and H₂O vapor. According to embodiments of the invention, the formation of the modified SiARC layer 512 and the modified OPL coating 524 enables subsequent complete removal of the modified SiARC layer 512 and the modified OPL coating 524 in a second wet process that includes exposing the modified SiARC layer 512 and the modified OPL coating 524 to DHF and centrifugally removing the layers (512 and 524). It is speculated that subsequent complete removal of the modified SiARC layer 512 and the modified OPL coating 524 in the second wet process is facilitated by damage in the form of cracks 514 in the modified SiARC layer 512 and the modified OPL coating 524. It is further speculated that the SiARC layer 506 is modified by the O₃ gas exposure, or by the O₃ gas and H₂O vapor exposure, to become more “SiO₂-like”, and the OPL coating 504 is modified to become more water soluble and therefore more easily removed.

According to embodiments of the invention, the second wet process removes the modified SiARC layer 512 and the modified OPL coating 524 from the oxide layer 502. The second wet process may be performed in a second processing system 300 schematically shown in FIG. 3 and described above.

FIG. 5D shows a film structure 53 following a second wet process for removing the modified SiARC layer 512 and the modified OPL coating 524.

According to one embodiment, the film structure 52 may be exposed to the cleaning liquid and, subsequently, without further exposure to the cleaning liquid, the substrate may be rotated to centrifugally remove the modified SiARC layer 512 and the modified OPL coating 524 from the film structure 52.

According another embodiment, the film structure 52 may be simultaneously exposed to the DHF liquid and the substrate rotated to centrifugally remove the modified SiARC layer 112 and the modified OPL coating 524 from the film structure 52.

According to another embodiment, the film structure 50 containing the photoresist pattern 508 and the SiARC layer 506 shown in FIG. 5A may be removed using a first process that includes an exposure to O₃ gas in the process chamber 210, followed by a second wet process includes exposing the modified SiARC layer 512 and the modified OPL coating 524 to DHF liquid, and centrifugally removing the layers 512 and 524. A DIW exposure and spinning may be used to remove the DHF liquid.

According to another embodiment, the film structure 50 containing the photoresist pattern 508 and the SiARC layer 506 shown in FIG. 5A may be removed using a first process that includes an exposure to a mixture of O₃ gas and H₂O vapor in the process chamber 210, followed by a second wet process includes exposing the modified SiARC layer 512 and the modified OPL coating 524 to DHF liquid, and centrifugally removing the layers 512 and 524. A DIW exposure and spinning may be used to remove the DHF liquid.

As shown in FIG. 5E, following the removal of the modified SiARC layer 512 and the modified OPL coating 524, a new OPL coating 516, a new SiARC layer 518, and a new photoresist 520 are deposited on the oxide layer 502 and the photoresist patterning process is repeated on the film structure 54. FIG. 5F shows a new film structure 55 that includes a new photoresist pattern 522 formed on the new SiARC layer 518.

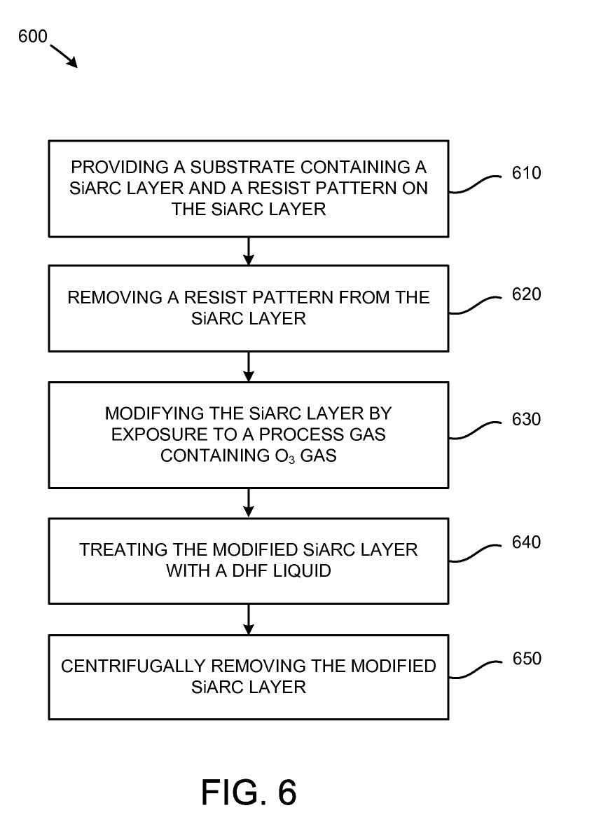

FIG. 6 is a simplified process flow diagram for a method of reworking a film structure containing a SiARC layer according to an embodiment of the invention. In block 610, at least one substrate is provided that contains a SiARC layer thereon, and a resist pattern formed on the SiARC layer.

In block 620, the resist pattern is removed from the SiARC layer.

In block 630, the SiARC layer is modified by exposure to a process gas containing O₃ gas and optionally H₂O vapor.

In block 640, the modified SiARC layer is treated with a DHF liquid. A DIW exposure and spinning may be used to remove the DHF liquid.

In block 650, the modified SiARC layer is centrifugally removed from the substrate.

According to one embodiment, the modified SiARC layer may be exposed to the DHF liquid in block 640 and, subsequently, without further exposure to the DHF liquid, the modified SiARC layer may be rotated in block 650 to centrifugally remove the modified SiARC layer from the substrate.

According to one embodiment, the processing in blocks 640 and 650 may be performed simultaneously or may at least partially overlap in time. In one example, the modified SiARC layer may be simultaneously exposed to the DHF liquid and rotated to centrifugally remove the modified SiARC layer from the substrate.

According to one embodiment, the processing in blocks 620 and 630 may be performed simultaneously by exposing the photoresist pattern and the SiARC layer to O₃ gas, and optionally N₂ gas. Subsequently, the modified SiARC layer and any remains of the resist pattern are treated with DHF liquid in block 640 and centrifugally removed in block 650.

According to another embodiment, the processing in blocks 620 and 630 may be performed simultaneously by exposing the photoresist pattern and the SiARC layer to a process gas containing O₃ gas, H₂O vapor, and optionally N₂ gas. Subsequently, the modified SiARC layer and any remains of the resist pattern are treated with a liquid containing DHF in block 640 and centrifugally removed in block 650.

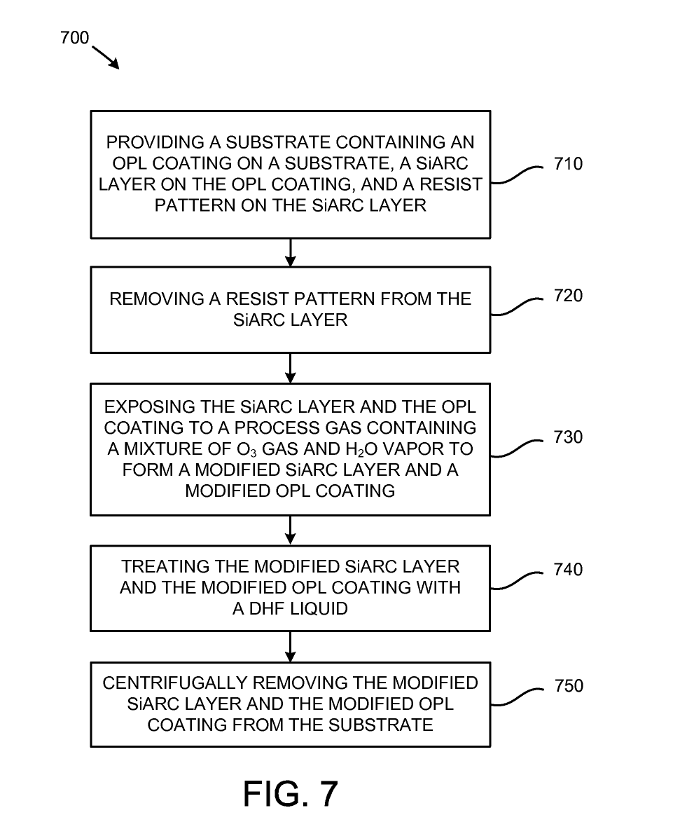

FIG. 7 is a simplified process flow diagram for a method of reworking a film structure containing a SiARC layer according to another embodiment of the invention. In block 710, at least one substrate is provided that contains an OPL coating thereon, a SiARC layer on the OPL coating, and a resist pattern formed on the SiARC layer.

In block 720, the resist pattern is removed from the SiARC layer.

In block 730, the SiARC layer and the OPL coating layer are modified by exposure to a process gas containing O₃ gas and optionally H₂O vapor.

In block 740, the modified SiARC layer and the OPL coating layer are treated with DHF liquid. A DIW exposure and spinning may be used to remove the DHF liquid.

In block 750, the modified SiARC layer and the modified OPL coating are centrifugally removing from the substrate.

According to one embodiment, the modified SiARC layer may be exposed to the DHF liquid in block 740 and, subsequently, without further exposure to the DHF liquid, the modified SiARC layer may be rotated in block 750 to centrifugally remove the modified SiARC layer and the modified OPL coating from the substrate.

According to one embodiment, the processing in blocks 740 and 750 may be performed simultaneously or may at least partially overlap in time. In one example, the modified SiARC layer may be simultaneously exposed to the DHF liquid and rotated to centrifugally remove the modified SiARC layer and the modified OPL coating from the substrate.

According to one embodiment, the processing in blocks 720 and 730 may be performed simultaneously by exposing the photoresist pattern and the SiARC layer to O₃ gas, and optionally N₂ gas. Subsequently, the modified SiARC layer and any remains of the resist pattern are treated with a liquid containing DHF in block 740 and centrifugally removed in block 650 along with the OPL coating.

According to another embodiment, the processing in blocks 720 and 730 may be performed simultaneously by exposing the photoresist pattern and the SiARC layer to a process gas containing O₃ gas, H₂O vapor, and optionally N₂ gas. Subsequently, the modified SiARC layer and any remains of the resist pattern are treated with a liquid containing DHF in block 740 and centrifugally removed in block 750 along with the modified OPL coating.

A plurality of embodiments for reworking film structures containing SiARC layers have been described. The foregoing description of the embodiments of the invention has been presented for the purposes of illustration and description. It is not intended to be exhaustive or to limit the invention to the precise forms disclosed. This description and the claims following include terms that are used for descriptive purposes only and are not to be construed as limiting. For example, the term “on” as used herein (including in the claims) does not require that a film “on” a substrate is directly on and in immediate contact with the substrate; there may be a second film or other structure between the film and the substrate.

Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

1. A method for reworking a substrate, the method comprising:
providing at least one substrate containing a silicon-containing anti-reflective coating (SiARC) layer thereon, and a resist pattern formed on the SiARC layer;
removing the resist pattern from the SiARC layer;
exposing the SiARC layer to a process gas containing ozone (O₃) gas to form a modified SiARC layer;
treating the modified SiARC layer with a dilute hydrofluoric acid (DHF) liquid; and
centrifugally removing the modified SiARC layer from the substrate.

2. The method of claim 1, wherein the exposing comprises:
exposing the SiARC layer to a process gas containing a mixture of O₃ gas and H₂O vapor to form the modified SiARC layer.

3. The method of claim 1, wherein the process gas is heated to a temperature between about 80° C. and about 150° C.

4. The method of claim 1, wherein the removing and exposing include simultaneously exposing the resist pattern and the SiARC layer to the process gas containing the O₃ gas.

5. The method of claim 4, wherein the process gas further comprises H₂O vapor.

6. The method of claim 1, wherein the treating and the centrifugally removing have at least partial temporal overlap.

7. The method of claim 1, wherein the treating and the centrifugally removing have no temporal overlap.

8. The method of claim 1, wherein the SiARC layer has a Si-content between about 10% and about 40%

9. The method of claim 1, wherein the SiARC layer has a Si-content greater than about 40%.

10. The method of claim 1, further comprising:
following the centrifugally removing, depositing a new SiARC layer on the substrate; and
forming a new resist pattern on the new SiARC layer.

11. A method for reworking a substrate, the method comprising:
providing at least one substrate containing an organic planarization layer (OPL) coating thereon, a silicon-containing anti-reflective coating (SiARC) layer on the OPL coating, and a resist pattern formed on the SiARC layer;
removing the resist pattern from the SiARC layer;
exposing the SiARC layer to a process gas containing a mixture of O₃ gas and H₂O vapor to form a modified SiARC layer and a modified OPL coating;
treating the modified SiARC layer and the modified OPL coating with a dilute hydrofluoric acid (DHF) liquid; and
centrifugally removing the modified SiARC layer and the modified OPL coating from the substrate.

12. The method of claim 11, wherein the process gas is heated to a temperature between about 80° C. and about 150° C.

13. The method of claim 11, wherein the removing and exposing include simultaneously exposing the resist pattern and the SiARC layer to the process gas containing the mixture of O₃ gas and H₂O vapor.

14. The method of claim 11, wherein the treating and the centrifugally removing have at least partial temporal overlap.

15. The method of claim 11, wherein the treating and the centrifugally removing have no temporal overlap.

16. The method of claim 11, wherein the SiARC layer has a Si-content between about 10% and about 40%

17. The method of claim 11, wherein the SiARC layer has a Si-content greater than about 40%.

18. (canceled)

19. The method of claim 11, wherein the substrate further comprises an oxide layer below the OPL coating, and a low-k layer below the oxide layer.

20. The method of claim 11, further comprising:
following the centrifugally removing, depositing a new SiARC layer on the substrate; and
forming a new resist pattern on the new SiARC layer.

21. A method for reworking a substrate, the method comprising:
providing at least one substrate containing an optical mask layer thereon, a silicon-containing anti-reflective coating (SiARC) layer on the optical mask layer, and a resist pattern formed on the SiARC layer;
removing the resist pattern from the SiARC layer;
exposing the SiARC layer to a process gas containing a mixture of O₃ gas and H₂O vapor to form a modified SiARC layer;
treating the modified SiARC layer and the optical mask layer with a dilute hydrofluoric acid (DHF) liquid; and
centrifugally removing the modified SiARC layer and the optical mask layer from the substrate.
